(19) United States
(12) Patent Application Publication
(10) Pub. No.: US 2019/0190533 A1
(43) Pub. Date: Jun. 20, 2019

(54) WIDEBAND SIGMA DELTA MODULATOR RECEIVER FOR FM SIGNAL RECEPTION

(71) Applicant: GM GLOBAL TECHNOLOGY OPERATIONS LLC, DETROIT, MI (US)

(72) Inventors: CYNTHIA D BARINGER, PIEDMONT, CA (US); MOHIUDDIN AHMED, MOORPARK, CA (US); JONGCHAN KANG, MOORPARK, CA (US); JAMES CHINGWEI LI, SIMI VALLEY, CA (US); EMILIO A SOVERO, THOUSAND OAKS, CA (US); TIMOTHY J TALTY, BEVERLY HILLS, MI (US)

(21) Appl. No.: 15/846,847

(22) Filed: Dec. 19, 2017

(51) Int. Cl. H03M 3/00; H04B 1/00

(52) U.S. Cl. CPC H03M 3/42; H04B 1/082; H04B 1/001; H03M 3/462

(57) ABSTRACT

A method and apparatus for utilizing a wideband radio frequency filter to capture an FM frequency band and configuring the characteristics of a delta-sigma modulator in order to processes desired signals within the FM frequency band. Specifically, the system and method are operative to receive a plurality of FM signals within an FM frequency band, filter the frequency band using a wideband filter, modulating the plurality of FM signals using a delta sigma modulator, down converting and processing the desired signals in parallel.

### BACKGROUND

The present application generally relates to wide bandwidth radio systems designed to adapt to various global radio standards and, more particularly, to a cellular radio architecture that employs FM receiver architecture capable of providing digital representations of all signals in the FM band. The architecture is based on a single wideband delta sigma modulator that captures all signals in the FM band and can simultaneously produce digital representation of each of the signals.

### DISCUSSION OF THE RELATED ART

Traditional cellular telephones employ different modes and bands of operation that have been supported in hardware by having multiple disparate radio front-end and baseband processing chips integrated into one platform, such as tri-band or quad-band user handsets supporting global system for mobile communications (GSM), general packet radio service (GPRS), etc. Known cellular receivers have integrated some of the antenna and baseband data paths, but nevertheless the current state of the art for mass mobile and vehicular radio deployment remains a multiple static channelizing approach. Such a static architecture is critically dependent on narrow-band filters, duplexers and standard-specific down-conversion to intermediate-frequency (IF) stages. The main disadvantage of this static, channelized approach is its inflexibility with regards to the changing standards and modes of operation. As the cellular communications industry has evolved from 2G, 3G, 4G and beyond, each new waveform and mode has required a redesign of the RF front-end of the receiver as well as expanding the baseband chip set capability, thus necessitating a new handset. For automotive applications, this inflexibility to support emerging uses is prohibitively expensive and a nuisance to the end-user.

Providing reliable automotive wireless access is challenging from an automobile manufacturers point of view because cellular connectivity methods and architectures vary across the globe. Further, the standards and technologies are ever changing and typically have an evolution cycle that is several times faster than the average service life of a vehicle. More particularly, current RF front-end architectures for vehicle radios are designed for specific RF frequency bands. Dedicated hardware tuned at the proper frequency needs to be installed on the radio platform for the particular frequency band that the radio is intended to operate at. Thus, if cellular providers change their particular frequency band, the particular vehicle that the previous band was tuned for, which may have a life of 15 to 20 years, may not operate efficiently at the new band. Hence, this requires automobile manufactures to maintain a myriad of radio platforms, components and suppliers to support each deployed standard, and to provide a path to upgradability as the cellular landscape changes, which is an expensive and complex proposition.

Delta-sigma modulators are becoming more prevalent in digital receivers because, in addition to providing wideband high dynamic range operation, the modulators have many tunable parameters making them a good candidate for reconfigurable systems. In particular, delta-sigma modulators include a software tunable filter for noise shaping an incoming RF signal. It would be desirable to utilize the software programmable nature of the delta-sigma modulator to further reduce the processing load of a system digital signal processor.

### SUMMARY

Embodiments according to the present disclosure provide a number of advantages. For example, embodiments according to the present disclosure may enable reception of control data for use by autonomous vehicle software, subsystems and the like. This system may further be employed to receive entertainment, audio, and video programming and is not limited to autonomous vehicles.

The present disclosure describes a method for filtering a first analog signal from within a first bandwidth of frequencies comprising receiving the first analog signal carrying a first data and a second analog signal carrying a second data, filtering the first analog signal and the second analog signal over the first bandwidth wherein the first analog signal is centered at a first frequency within the first bandwidth and the second analog signal is centered at a second frequency within the first bandwidth, delta sigma modulating the first analog signal and the second analog signal to generate a first digital signal, down sampling the first digital signal to generate a baseband digital signal, and processing the baseband digital signal to extract the first data.

Another aspect of the present disclosure describes a method for configuring a delta signal modulator comprising receiving a first analog signal carrying a first data within a first bandwidth of frequencies, amplifying the first analog signal to generate an amplified analog signal, filtering the amplified analog signal over the first bandwidth of frequencies to generate a filtered analog signal, modulating the filtered analog signal according to a delta sigma modulation to generate a first digital signal, decimating the first digital signal to generate a second digital signal, and processing the second digital signal to extract the first data.

Another aspect of the present disclosure describes an apparatus comprising an antenna for receiving a first analog signal carrying a first data within a first bandwidth of frequencies, a low noise amplifier for amplifying the first analog signal to generate an amplified analog signal, a filter for filtering the amplified analog signal over the first bandwidth of frequencies to generate a filtered analog signal, a delta sigma modulator for modulating the filtered analog signal to generate a first digital signal, a decimator for down sampling the first digital signal to generate a second digital signal, and a baseband processor for processing the second digital signal to extract the first data.

Additional features of the present invention will become apparent from the following description and appended claims, taken in conjunction with the accompanying drawings.

### BRIEF DESCRIPTION OF THE DRAWINGS

FIG. 1 shows a block diagram of a known multi-mode, multi-band cellular communications handset architecture.

FIG. 2 shows a block diagram of a software-programmable cellular radio architecture applicable.

FIG. 3 shows an exemplary system for implementing a wideband sigma delta modulator receiver in a software defined radio.

FIG. 4 shows an exemplary method for implementing a wideband sigma delta modulator receiver in a software defined radio.

### DETAILED DESCRIPTION OF THE EMBODIMENTS

The following discussion of the embodiments of the invention directed to a cellular radio architecture is merely exemplary in nature, and is in no way intended to limit the invention or its applications or uses. For example, the radio architecture of the invention is described as having application for a vehicle. However, as will be appreciated by those skilled in the art, the radio architecture may have applications other than automotive applications.

The cellular radio architectures discussed herein are applicable to more than cellular wireless technologies, for example, WiFi (IEEE 802.11) technologies. Further, the cellular radio architectures are presented as a fully duplexed wireless system, i.e., one that both transmits and receives. For wireless services that are receive only, such as global positioning system (GPS), global navigation satellite system (GNSS) and various entertainment radios, such as AM/FM, digital audio broadcasting (DAB), SiriusXM, etc., only the receiver design discussed herein would be required. Also, the described radio architecture design will enable one radio hardware design to function globally, accommodating various global wireless standards through software updates. It will also enable longer useful lifespan of the radio hardware design by enabling the radio to adapt to new wireless standards when they are deployed in the market. For example, 4G radio technology developments and frequency assignments are very dynamic. Thus, radio hardware deployed in the market may become obsolete after just one or two years. For applications, such as in the automotive domain, the lifespan can exceed ten years. This invention enables a fixed hardware platform to be updateable through software updates, thus extending the useful lifespan and global reuse of the hardware.

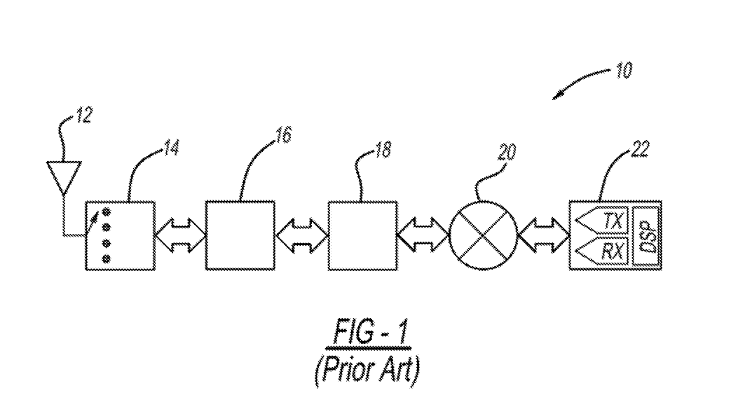

FIG. 1 is a block diagram of a known multi-mode, multi-band cellular communications user handset architecture 10 for a typical cellular telephone. The architecture 10 includes an antenna structure 12 that receives and transmits RF signals at the frequency band of interest. The architecture 10 also includes a switch 14 at the very front-end of the architecture 10 that selects which particular channel the transmitted or received signal is currently for and directs the signal through a dedicated set of filters and duplexers represented by box 16 for the particular channel. Modules 18 provide multi-mode and multi-band analog modulation and demodulation of the receive and transmit signals and separates the signals into in-phase and quadrature-phase signals sent to or received from a transceiver 20. The transceiver 20 also converts analog receive signals to digital signals and digital transmit signals to analog signals. A baseband digital signal processor 22 provides the digital processing for the transmit or receive signals for the particular application.

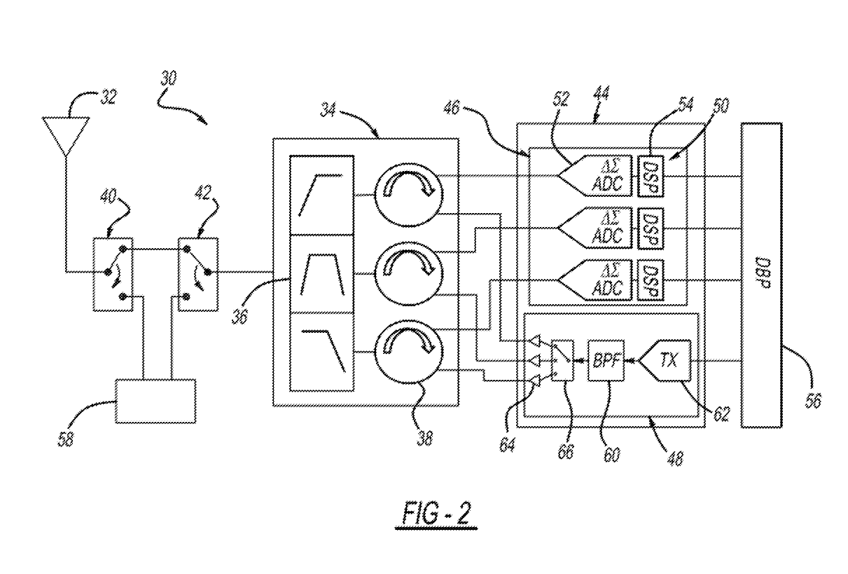

FIG. 2 is a schematic block diagram of a cellular radio front-end architecture 30 that provides software programmable capabilities as will be discussed in detail below. The architecture 30 includes an antenna structure 32 capable of receiving and transmitting the cellular frequency signals discussed herein, such as in a range of 400 MHz-3.6 GHz. Signals received and transmitted by the antenna structure 32 go through a multiplexer 34 that includes three signal paths, where each path is designed for a particular frequency band as determined by a frequency selective filter 36 in each path. In this embodiment, three signal paths have been selected, however, the architecture 30 could be expanded to any number of signal paths. Each signal path includes a circulator 38 that separates and directs the receive and transmit signals, and provides isolation so that the high power signals being transmitted do not enter the receiver side and saturate the receive signals at those frequency bands.

The architecture 30 also includes a front-end transceiver module 44 that is behind the multiplexer 34 and includes a receiver module 46 that processes the receive signals and a transmitter module 48 that processes the transmit signals. The receiver module 46 includes three receiver channels 50, one for each of the signal paths through the multiplexer 34, where a different one of the receiver channels 50 is connected to a different one of the circulators 38, as shown. Each of the receiver channels 50 includes a delta-sigma modulator 52 that receives the analog signal at the particular frequency band and generates a representative stream of digital data using an interleaving process in connection with a number of N-bit quantizer circuits operating at a very high clock rate, as will be discussed in detail below. As will further be discussed, the delta-sigma modulator 52 compares the difference between the receive signal and a feedback signal to generate an error signal that is representative of the digital data being received. The digital data bits are provided to a digital signal processor (DSP) 54 that extracts the digital data stream. A digital baseband processor (DBP) 56 receives and operates on the digital data stream for further signal processing in a manner well understood by those skilled in the art. The transmitter module 48 receives digital data to be transmitted from the processor 56. The module 48 includes a transmitter circuit 62 having a delta-sigma modulator that converts the digital data from the digital baseband processor 56 to an analog signal. The analog signal is filtered by a tunable bandpass filter (BPF) 60 to remove out of band emissions and sent to a switch 66 that directs the signal to a selected power amplifier 64 optimized for the transmitted signal frequency band. In this embodiment, three signal paths have been selected, however, the transmitter module 48 could be implemented using any number of signal paths. The amplified signal is sent to the particular circulator 38 in the multiplexer 34 depending on which frequency is being transmitted.

As will become apparent from the discussion below, the configuration of the architecture 30 provides software programmable capabilities through high performance delta-sigma modulators that provide optimized performance in the signal band of interest and that can be tuned across a broad range of carrier frequencies. The architecture 30 meets current cellular wireless access protocols across the 0.4-2.6 GHz frequency range by dividing the frequency range into three non-continuous bands. However, it is noted that other combinations of signal paths and bandwidth are of course possible. The multiplexer 34 implements frequency domain de-multiplexing by passing the RF carrier received at the antenna structure 32 into one of the three signal paths. Conversely, the transmit signal is multiplexed through the multiplexer 34 onto the antenna structure 32. For vehicular wireless access applications, such a low-cost integrated device is desirable to reduce parts cost, complexity, obsolescence and enable seamless deployment across the globe.

The delta-sigma modulators 52 may be positioned near the antenna structure 32 so as to directly convert the RF receive signals to bits in the receiver module 46 and bits to an RF signal in the transmitter module 48. The main benefit of using the delta-sigma modulators 52 in the receiver channels 50 is to allow a variable signal capture bandwidth and variable center frequency. This is possible because the architecture 30 enables software manipulation of the modulator filter coefficients to vary the signal bandwidth and tune the filter characteristics across the RF band, as will be discussed below.

The architecture 30 allows the ability to vary signal capture bandwidth, which can be exploited to enable the reception of continuous carrier aggregated waveforms without the need for additional hardware. Carrier aggregation is a technique by which the data bandwidths associated with multiple carriers for normally independent channels are combined for a single user to provide much greater data rates than a single carrier. Together with MIMO, this feature is a requirement in modern 4G standards and is enabled by the orthogonal frequency division multiplexing (OFDM) family of waveforms that allow efficient spectral usage.

The architecture 30 through the delta-sigma modulators 52 can handle the situation for precise carrier aggregation scenarios and band combinations through software tuning of the bandpass bandwidth, and thus enables a multi-segment capture capability. Dynamic range decreases for wider bandwidths where more noise is admitted into the sampling bandpass. However, it is assumed that the carrier aggregation typically makes sense when the user has a good signal-to-noise ratio, and not cell boundary edges when connectivity itself may be marginal. Note that the inter-band carrier aggregation is automatically handled by the architecture 30 since the multiplexer 34 feeds independent modulators in the channels 50.

The circulators 38 route the transmit signals from the transmitter module 48 to the antenna structure 32 and also provide isolation between the high power transmit signals and the receiver module 46. Although the circulators 38 provide significant signal isolation, there is some port-to-port leakage within the circulator 38 that provides a signal path between the transmitter module 48 and the receiver module 46. A second undesired signal path occurs due to reflections from the antenna structure 32, and possible other components in the transceiver. As a result, a portion of the transmit signal will be reflected from the antenna structure 32 due to a mismatch between the transmission line impedance and the antenna's input impedance. This reflected energy follows the same signal path as the incoming desired signal back to the receiver module 46.

The architecture 30 is also flexible to accommodate other wireless communications protocols. For example, a pair of switches 40 and 42 can be provided that are controlled by the DBP 56 to direct the receive and transmit signals through dedicated fixed RF devices 58, such as a global system for mobile communications (GSM) RF front-end module or a WiFi front-end module. In this embodiment, some select signal paths are implemented via conventional RF devices. FIG. 2 only shows one additional signal path, however, this concept can be expanded to any number of additional signal paths depending on use cases and services.

Delta-sigma modulators are a well known class of devices for implementing analog-to-digital conversion. The fundamental properties that are exploited are oversampling and error feedback (delta) that is accumulated (sigma) to convert the desired signal into a pulse modulated stream that can subsequently be filtered to read off the digital values, while effectively reducing the noise via shaping. The key limitation of known delta-sigma modulators is the quantization noise in the pulse conversion process. Delta-sigma converters require large oversampling ratios in order to produce a sufficient number of bit-stream pulses for a given input. In direct-conversion schemes, the sampling ratio is greater than four times the RF carrier frequency to simplify digital filtering. Thus, required multi-GHz sampling rates have limited the use of delta-sigma modulators in higher frequency applications. Another way to reduce noise has been to use higher order delta-sigma modulators. However, while first order canonical delta-sigma architectures are stable, higher orders can be unstable, especially given the tolerances at higher frequencies. For these reasons, state of the art higher order delta-sigma modulators have been limited to audio frequency ranges, i.e., time interleaved delta-sigma modulators, for use in audio applications or specialized interleaving at high frequencies.

The filter characteristics of a Delta-Sigma modulator may effectively be modified in order to compensate for Doppler shift. Doppler shift occurs when the transmitter of a signal is moving in relation to the receiver. The relative movement shifts the frequency of the signal, making it different at the receiver than at the transmitter. An exemplary system according to the present disclosure leverages the software-defined radio architecture to quickly estimate a shift in the carrier frequency and re-center the filter before the signal is disrupted or degraded. In normal operation, the notch of the modulator filter is centered about the expected carrier frequency of the received signal with the signal band information centered around the carrier frequency and not exceeding the bandwidth of the modulator filter. A Doppler shift would offset the carrier by an amount Δf causing potential degradation to signal content with an increase in noise at one side of the band. According to the method and system described herein, the transceiver in a wireless cellular communication system can adapt to changes in the RF carrier frequency and may maintain signal integrity, by shifting the filter notch by the same amount as the carrier frequency.

For the cellular application discussed herein that covers multiple assigned frequency bands, a transmitter with multi-mode and multi-band coverage is required. Also, many current applications mandate transmitters that rapidly switch between frequency bands during the operation of a single communication link, which imposes significant challenges to typical local oscillator (LO) based transmitter solutions. This is because the switching time of the LO-based transmitter is often determined by the LO channel switching time under the control of the loop bandwidth of the frequency synthesizer, around 1 MHz. Hence, the achievable channel switching time is around several microseconds, which unfortunately is too long for an agile radio. A fully digital PWM based multi-standard transmitter, known in the art, suffers from high distortion, and the channel switching time is still determined by the LO at the carrier frequency. A DDS can be used as the LO sourced to enhance the switching speed, however, this design consumes significant power and may not deliver a high frequency LO with low spurious components. Alternately, single sideband mixers can be used to generate a number of LOs with different center frequencies using a common phase-lock loop (PLL), whose channel switching times can be fast. However, this approach can only support a limited number of LO options and any additional channels to cover the wide range of the anticipated 4G bands would need extra mixtures. As discussed, sigma-delta modulators have been proposed in the art to serve as an RF transmitter to overcome these issues. However, in the basic architecture, a sigma-delta modulator cannot provide a very high dynamic range in a wideband of operations due to a moderate clock frequency. It is precisely because the clock frequency is constrained by current technology that this high frequency mode of operations cannot be supported.

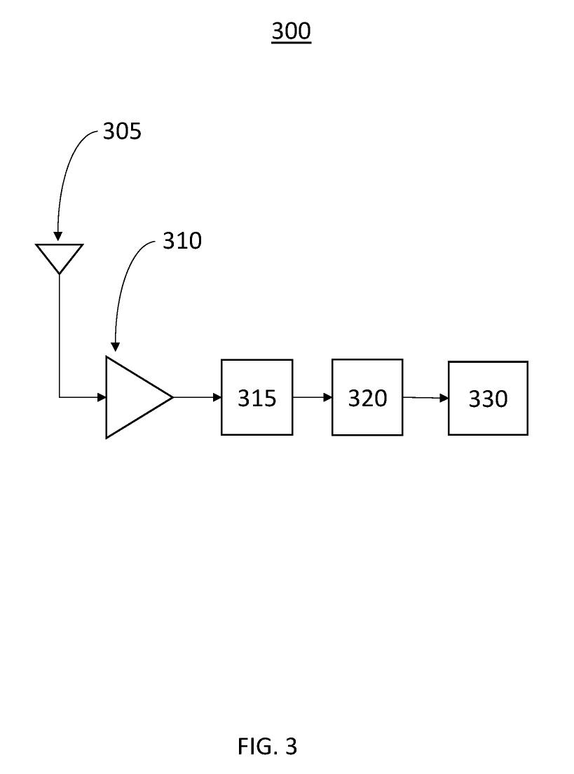

Turning now to FIG. 3, an exemplary system for implementing a wideband sigma delta modulator receiver 300 in a software defined radio is shown. The system comprises an antenna 305, a low noise transconductance amplifier (LNTA) 310, a tunable bandpass delta sigma modulator 315, a decimation filter 320, and a digital baseband processor (DBP) 330. A sigma delta data converter based wideband FM receiver that can simultaneously capture entire commercial FM band. Via digital signal processing, the receiver can extract multiple FM channels for demodulation and output, thus making multiple tuner based channel scanning unnecessary. Furthermore, the proposed system may enable full software and digital control of entire FM band processing for commercial radio receiver applications.

The antenna 305 is operative to receive all signals over the entire commercial FM band. This may be achieved by a single antenna, or a combination of antennas with or without individual amplifiers and/or bandpass filters. The antenna for the FM band may be a monopole antenna or a planar antenna mounted on a glass surface of a vehicle. Specifically, the system may employ an asymmetrical tapered bowtie antenna to increase the bandwidth of operation.

The signals received by the antenna 305 are then coupled to an LNTA 310, or the like, for amplification. Alternatively, a traditional low noise amplifier (LNA) may be used. LNTA introduces non-linearity in exchange for lower noise figure, while the opposite is true for an LNA. The amplified signal is then coupled from the LNTA to the tunable bandpass delta sigma modulator 315.

The tunable bandpass delta sigma modulator 315 is operative to receive the amplified signal at Fₛ/2 within a band of interest at the RF carrier (88-108 MHz) and to convert the signal into a digital representation. The modulator 315 has a tuneable filter, and an M-bit quantizer clocked at K*Fs. The decimation filter 320 brings the information of the selected signal to baseband. In practice a notch filter center frequency is shifted to the desired signal frequency. The modulator is capable of achieving high dynamic range over the narrow signal band through oversampling (by a factor K). In an exemplary embodiment, the bandpass delta sigma modulator may have a fixed bandwidth of 20 MHz with a 4th order, 3 bit modulator with an LC resonator

The baseband signal from the decimation filter is then coupled to a digital baseband processor (BDP) 330 for signal processing. The BDP will parse the data and extract all available information currently sent with the audio signal. Without having to add separate tuners for scanning stations, searching traffic announcements, or a variety of other commercial features included in a Radio Data System (RDS) service, all data will be readily available.

The proposed system is desirable as no additional circuitry is required to bring the RF carrier to an intermediate frequency (IF) before processing. However, only one single frequency is selected for processing so additional tuning is required to capture all the information available in current FM systems wherein a fixed bandpass modulator may be employed for capturing the entire band. Extraction of the signals, data, and information will be performed entirely in the digital domain.

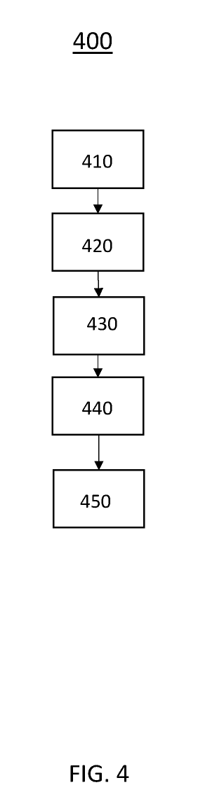

Turning now to FIG. 4, an exemplary method for implementing a wideband sigma delta modulator receiver 400 in a software defined radio is shown. The proposed method is first operative to receive a frequency modulated signal 410 within a first band of frequencies. The received signal is then amplified to within an amplitude range suitable for further processing 420 to generate an amplified signal. The amplified signal is then filtered using a delta sigma modulator 430 to generate a digital signal representing the received analog signal. The digital signal is then decimated 440 in order to reduce the sampling rate of the signal. This produces an approximation of the digital sequence generated by the delta signal modulator which is then coupled to the BDP for signal extraction and further processing 450.

As will be well understood by those skilled in the art, the several and various steps and processes discussed herein to describe the invention may be referring to operations performed by a computer, a processor or other electronic calculating device that manipulate and/or transform data using electrical phenomenon. Those computers and electronic devices may employ various volatile and/or non-volatile memories including non-transitory computer-readable medium with an executable program stored thereon including various code or executable instructions able to be performed by the computer or processor, where the memory and/or computer-readable medium may include all forms and types of memory and other computer-readable media.

The foregoing discussion disclosed and describes merely exemplary embodiments of the present invention. One skilled in the art will readily recognize from such discussion and from the accompanying drawings and claims that various changes, modifications and variations can be made therein without departing from the spirit and scope of the invention as defined in the following claims.

What is claimed is:

1. A method for configuring a delta signal modulator comprising:
receiving a first analog signal carrying a first data within a first bandwidth of frequencies;
amplifying the first analog signal to generate an amplified analog signal;
filtering the amplified analog signal over the first bandwidth of frequencies to generate a filtered analog signal;
modulating the filtered analog signal according to a delta sigma modulation to generate a first digital signal;
decimating the first digital signal to generate a second digital signal; and
processing the second digital signal to extract the first data.

2. The method of claim 1 further comprising a second analog signal within the first bandwidth of frequencies.

3. The method of claim 2 wherein the filtered analog signal includes the first analog signal and the second analog signal.

4. The method of claim 3 wherein processing the second digital signal extracts the first data and rejects a second data carried by a second analog signal within the first bandwidth of frequencies.

5. The method of claim 1 further comprising reconfiguring the delta signal modulation in response to the first analog signal such that the modulation is centered around a center frequency of the first analog signal.

6. The method of claim 1 further wherein the amplifying the first analog signal is performed in response to an amplitude of the first analog signal.

7. The method of claim 1 wherein the delta sigma modulation is operative to capture a plurality of analog signals within the first bandwidth of frequencies and wherein the processing the second digital signal is further operative to extract the first data from only one of the plurality of analog signals.

8. An apparatus comprising:
an antenna for receiving a first analog signal carrying a first data within a first bandwidth of frequencies;
a low noise amplifier for amplifying the first analog signal to generate an amplified analog signal;
a filter for filtering the amplified analog signal over the first bandwidth of frequencies to generate a filtered analog signal;
a delta sigma modulator for modulating the filtered analog signal to generate a first digital signal;
a decimator for down sampling the first digital signal to generate a second digital signal; and
a baseband processor for processing the second digital signal to extract the first data.

9. The apparatus of claim 8 further comprising a second analog signal within the first bandwidth of frequencies.

10. The apparatus of claim 9 wherein the filtered analog signal includes the first analog signal and the second analog signal.

11. The apparatus of claim 10 wherein processing the second digital signal extracts the first data and rejects a second data carried by a second analog signal within the first bandwidth of frequencies.

12. The apparatus of claim 8 further comprising reconfiguring the delta signal modulator in response to the first analog signal such that the modulation is centered around a center frequency of the first analog signal.

13. The apparatus of claim 8 further wherein the amplifying the first analog signal is performed in response to an amplitude of the first analog signal.

14. The apparatus of claim 8 wherein the delta sigma modulation is operative to capture a plurality of analog signals within the first bandwidth of frequencies and wherein the processing the second digital signal is further operative to extract the first data from only one of the plurality of analog signals.

15. A method for filtering a first analog signal from within a first bandwidth of frequencies comprising:
receiving the first frequency modulated analog signal carrying a first data and a second frequency modulated analog signal carrying a second data;
filtering the first frequency modulated analog signal and the second frequency modulated analog signal over the first bandwidth wherein the first frequency modulated analog signal is centered at a first frequency within the first bandwidth and the second frequency modulated analog signal is centered at a second frequency within the first bandwidth;
delta sigma modulating the first frequency modulated analog signal and the second frequency modulated analog signal to generate a first digital signal;
down sampling the first digital signal to generate a baseband digital signal; and
processing the baseband digital signal to extract the first data.

16. The method of claim 15 wherein processing the baseband digital signal extracts the first data and rejects the second data.

17. The method of claim 15 wherein the first data is an entertainment program.

18. The method of claim 15 further comprising centering the delta sigma modulation around the first frequency.

19. The method of claim 15 wherein the down sampling is performed by signal decimation.

20. The method of claim 15 further comprising processing the baseband digital signal to extract the second data.
